(19) United States
(12) Patent Application Publication
(10) Pub. No.: US 2025/0205104 A1
(43) Pub. Date: Jun. 26, 2025

(54) METHOD FOR DETECTING CONNECTION OF FASTENING FRAME, AND ELECTRONIC DEVICE PERFORMING METHOD

(71) Applicant: Samsung Electronics Co., Ltd., Suwon-si (KR)

(72) Inventor: Yonghyun PARK, Suwon-si (KR)

(21) Appl. No.: 19/075,095

(22) Filed: Mar. 10, 2025

Related U.S. Application Data
(63) Continuation of application No. PCT/KR2023/014179, filed on Sep. 19, 2023.

(30) Foreign Application Priority Data
Nov. 2, 2022 (KR) 10-2022-0144202

(51) Int. Cl. A61H 3/00; H04W 4/80

(52) U.S. Cl. CPC A61H 3/00; H04W 4/80; A61H 2003/007; A61H 2201/165

(57) ABSTRACT

An electronic device that detects the connection of a fastening frame, may receive a sensed magnetic flux value from a sensor module of the electronic device, determine that a fastening frame is connected to a housing of the electronic device if the received magnetic flux value is at or above a preset threshold value, and transmit, to a first external device, a first event signal corresponding to the connection of the fastening frame and the housing.

### CROSS-REFERENCE TO RELATED APPLICATIONS

This application is a continuation application of International Application No. PCT/KR2023/014179 designating the United States, filed on Sep. 19, 2023, in the Korean Intellectual Property Receiving Office and claiming priority to Korean Patent Application No. 10-2022-0144202, filed on Nov. 2, 2022, the disclosures of which are all hereby incorporated by reference herein in their entireties.

### BACKGROUND

### Technical Field

Certain example embodiments relate to technology for controlling a wearable device.

### Description of Related Art

A change into aging societies has contributed to a growing number of people who experience inconvenience and pain from reduced muscular strength or joint problems due to aging. Thus, there is a growing interest in walking assist devices that enable elderly users or patients with reduced muscular strength or joint problems to walk with less effort, and/or which allow persons to exercise.

### SUMMARY

According to an example embodiment, an electronic device may include a communication module configured to perform short-range wireless communication with an external device, wherein the communication module may include at least one processor comprising processing circuitry, a switch configured to power on the electronic device when the fastening frame is fastened to at least a portion of a housing including the electronic device, a sensor module configured to sense a magnetic flux of a magnetic body included in the fastening frame, and memory comprising one or more storage media storing instructions, when executed by the at least one processor individually or collectively, cause the electronic device to perform at least: receiving a magnetic flux value sensed by the sensor module, when the received magnetic flux value is greater than or equal to a preset threshold value, determining that the fastening frame is connected to the housing, and transmitting, to a first external device, a first event signal corresponding to a connection between the fastening frame and the housing.

According to an example embodiment, a method performed by an electronic device, may include receiving a magnetic flux value sensed by a sensor module of the electronic device, when the received magnetic flux value is greater than or equal to a preset threshold value, determining that a fastening frame is connected to the housing, and transmitting, to a first external device, a first event signal corresponding to a connection between the fastening frame and the housing.

According to an example embodiment, a method performed by a wearable device, may include receiving, from an electronic device connected to the wearable device via a wireless communication channel, a first event signal, wherein the first event signal is generated by the electronic device when a fastening is connected to at least a portion of a housing including the electronic device, when the first event signal is received, determining, based on sensing data, a value of a torque for controlling the wearable device, and controlling the wearable device by outputting the value of the torque through a motor driver circuit of the wearable device.

### BRIEF DESCRIPTION OF DRAWINGS

FIG. 1 is a diagram illustrating an overview of a wearable device worn on a body of a user, according to an example embodiment.

FIG. 2 is a diagram illustrating an exercise management system including a wearable device and an electronic device, according to an example embodiment.

FIG. 3 is a rear schematic view of a wearable device, according to an embodiment.

FIG. 4 is a left side view of a wearable device, according to an example embodiment.

FIGS. 5A and 5B are diagrams illustrating a configuration of a control system of a wearable device, according to an example embodiment.

FIG. 6 is a diagram illustrating an interaction between a wearable device and an electronic device, according to an example embodiment.

FIG. 7 is a diagram illustrating a configuration of an electronic device, according to an example embodiment.

FIG. 8 is a diagram illustrating a configuration of an electronic device for detecting a connection of a fastening frame, according to an example embodiment.

FIG. 9A is a diagram illustrating a non-connection state between a housing of an electronic device and a fastening frame, according to an embodiment, and FIG. 9B is a diagram illustrating a connection state between the housing of the electronic device and the fastening frame, according to an example embodiment.

FIG. 10 is a flowchart of a method of detecting a connection of a fastening frame, performed by an electronic device, according to an example embodiment.

FIG. 11 is a flowchart of a method of establishing a wireless channel with a first external device, according to an example embodiment.

FIG. 12 is a flowchart of a method of terminating an operation of an electronic device, based on an event signal received from a first external device, according to an example embodiment.

FIG. 13 is a flowchart of a method of terminating an operation of an electronic device when there is no response from a first external device to a beacon propagated by the electronic device, according to an example embodiment.

FIG. 14 is a flowchart of a method of transmitting, to a first external device, an event signal corresponding to separation of a fastening frame, according to an example embodiment.

FIG. 15 is a flowchart of a method of controlling a wearable device based on an event signal corresponding to a connection of a fastening frame, according to an example embodiment.

FIG. 16 is a flowchart of a method of transmitting, to an electronic device, an event signal corresponding to deactivation of an operation of a wearable device, according to an example embodiment.

FIG. 17 is a flowchart of a method of controlling a wearable device based on an event signal corresponding to separation of a fastening frame, according to an example embodiment.

### DETAILED DESCRIPTION

Hereinafter, various embodiments of the present disclosure will be described with reference to the accompanying drawings. However, this is not intended to limit the present disclosure to specific embodiments, and it should be understood that various modifications, equivalents, and/or alternatives of the embodiments of the present disclosure are included.

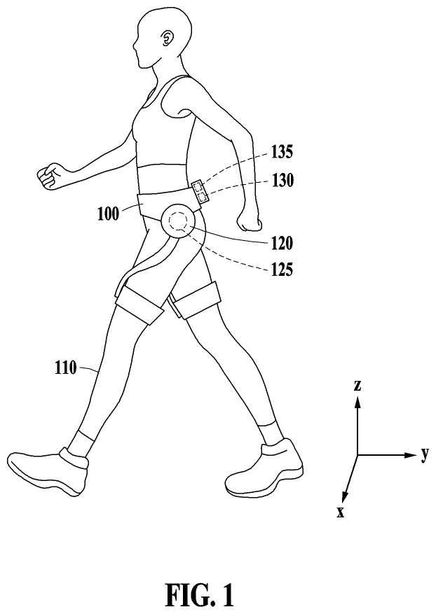

FIG. 1 is a diagram illustrating an overview of a wearable device worn on a body of a user, according to an embodiment.

Referring to FIG. 1, in an embodiment, a wearable device 100 may be a device worn on a body of a user 110 to assist the user 110 in walking, exercising, and/or working. In an embodiment, the wearable device 100 may be used to measure a physical ability (e.g., a walking ability, an exercise ability, or an exercise posture) of the user 110. In embodiments, the term “wearable device” may be replaced with “wearable robot,” “walking assistance device,” or “exercise assistance device.” The user 110 may be a human or an animal, but is not limited thereto. The wearable device 100 may be worn on a body (e.g., a lower body (the legs, ankles, knees, etc.), an upper body (the torso, arms, wrists, etc.), or the waist) of the user 110 to apply an external force such as an assistance force and/or a resistance force to a body motion of the user 110. The assistance force may be a force applied in the same direction as the body motion direction of the user 110, the force to assist a body motion of the user 110. The resistance force may be a force applied in a direction opposite to the body motion direction of the user 110, the force hindering a body motion of the user 110. The term “resistance force” may also be referred to as “exercise load.”

In an embodiment, the wearable device 100 may operate in a walking assistance mode for assisting the user 110 in walking. In the walking assistance mode, the wearable device 100 may assist the user 110 in walking by applying an assistance force generated by a driving module 120 of the wearable device 100 to the body of the user 110. The wearable device 100 may enable the user 110 to walk independently or to walk for a long time by providing a force required for the user 110 to walk, thereby extending the walking ability of the user 110. The wearable device 100 may help in improving an abnormal walking habit or gait posture of a walker.

In an embodiment, the wearable device 100 may operate in an exercise assistance mode for enhancing the exercise effect of the user 110. In the exercise assistance mode, the wearable device 100 may impede a body movement of the user 110 or provide resistance to the body movement of the user 110 by applying a resistance force generated from the driving module 120 to the body of the user 110. When the wearable device 100 is a hip-type wearable device that is worn on a waist (or pelvis) and legs (e.g., thighs) of the user 110, the wearable device 100 may provide an exercise load to a leg motion of the user 110 while being worn on the legs, thereby enhancing the exercise effect on the legs of the user 110. In an embodiment, the wearable device 100 may apply an assistance force to the body of the user 110 to assist the user 110 in exercising. For example, when a person with a disability or an elderly person wants to exercise by wearing the wearable device 100, the wearable device 100 may provide an assistance force to assist a body motion during an exercise process. In an embodiment, the wearable device 100 may provide an assistance force and a resistance force in combination for each exercise section or time section, in such a manner of providing an assistance force in some exercise sections and a resistance force in other exercise sections.

In an embodiment, the wearable device 100 may operate in a physical ability measurement mode for measuring a physical ability of the user 110. The wearable device 100 may measure motion information of a user using sensors (e.g., an angle sensor 125 and an inertial measurement unit (IMU) 135) provided in the wearable device 100 while the user is walking or exercising, and evaluate the physical ability of the user based on the measured motion information. For example, a gait index or an exercise ability indicator (e.g., muscular strength, endurance, balance, or exercise motion) of the user 110 may be estimated through the motion information of the user 110 measured by the wearable device 100. The physical ability measurement mode may include an exercise posture measurement mode for measuring an exercise posture of a user.

In embodiments of the present disclosure, for convenience of description, the wearable device 100 is described as an example of a hip-type wearable device, as illustrated in FIG. 1, but the embodiments are not limited thereto. As described above, the wearable device 100 may be worn on body parts (e.g., upper arms, lower arms, hands, calves, and feet) other than the waist and legs (particularly, the thighs), and a shape and configuration of the wearable device 100 may vary depending on the body part on which the wearable device 100 is worn.

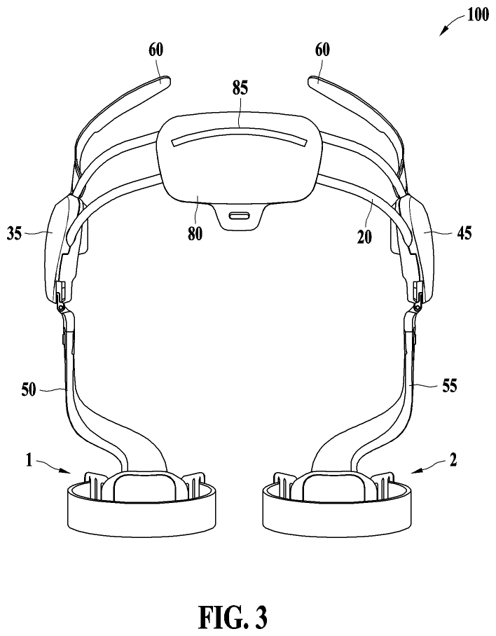

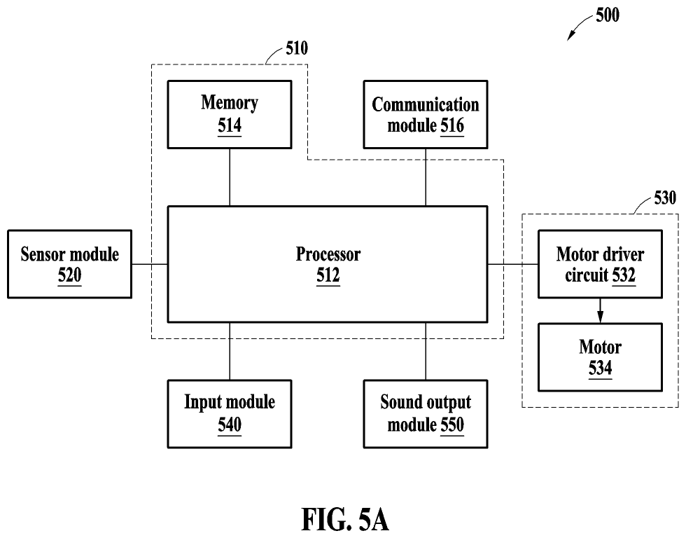

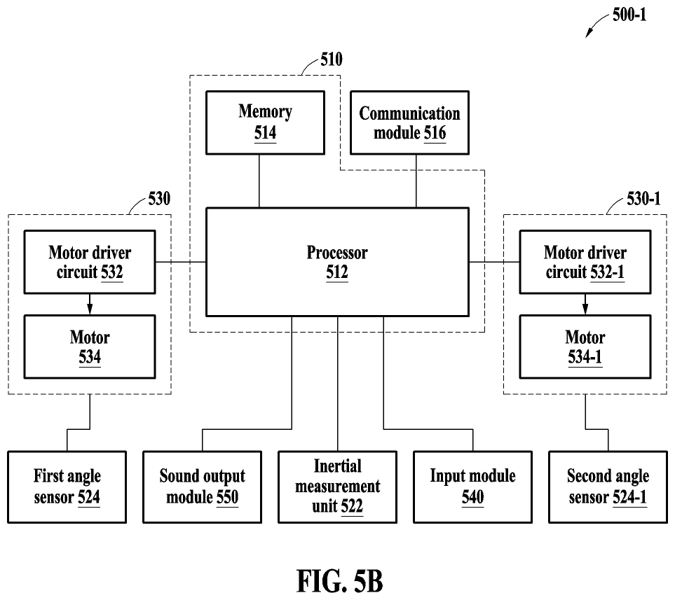

According to an embodiment, the wearable device 100 may include a support frame (e.g., leg support frames 50 and 55 and a waist support frame 20 of FIG. 3) configured to support the body of the user 110 when the wearable device 100 is worn on the body of the user 110, a sensor module (e.g., a sensor module 520 of FIG. 5A) configured to obtain sensor data including motion information on a body motion (e.g., a motion of a leg, and a motion of an upper body) of the user 110, the driving module 120 (e.g., driving modules 35 and 45 of FIG. 3) configured to generate torque to be applied to the legs of the user 110, and a control module 130 (e.g., a control module 510 of FIGS. 5A and 5B) configured to control the wearable device 100.

The sensor module may include the angle sensor 125 and the IMU 135. The angle sensor 125 may measure a rotation angle of a leg support frame of the wearable device 100 corresponding to a hip joint angle value of the user 110. The rotation angle of the leg support frame measured by the angle sensor 125 may be estimated as a hip joint angle value (or a leg angle value) of the user 110. The angle sensor 125 may include, for example, an encoder and/or a Hall sensor. In an embodiment, the angle sensor 125 may be present near each of a right hip joint and a left hip joint of the user 110. The IMU 135 may include an acceleration sensor and/or an angular velocity sensor, and may measure a change in acceleration and/or angular velocity according to a motion of the user 110. The IMU 135 may measure, for example, an upper body motion value of the user 110 corresponding to a motion value of a waist support frame (or a base body (a base body 80 of FIG. 3)) of the wearable device 100. A motion value of the waist support frame measured by the IMU 135 may be estimated as an upper body motion value of the user 110.

In an embodiment, the control module 130 and the IMU 135 may be arranged within the base body (e.g., the base body 80 of FIG. 3) of the wearable device 100. The base body may be disposed on a lumbar region (an area of the lower back) of the user 110 while the user 110 is wearing the wearable device 100. The base body may be formed on or attached to the outside of the waist support frame of the wearable device 100. The base body may be mounted on the lumbar region of the user 110 to provide a cushioning feeling to the lower back of the user 110 and may support the lower back of the user 110 together with the waist support frame.

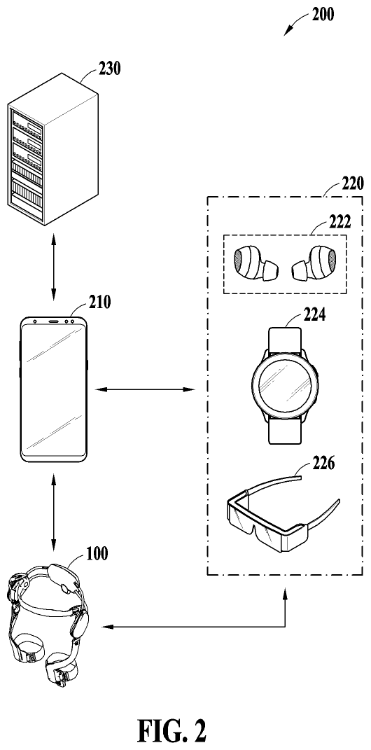

FIG. 2 is a diagram illustrating an exercise management system including a wearable device and an electronic device, according to an embodiment.

Referring to FIG. 2, an exercise management system 200 may include a wearable device 100 to be worn on a body of a user, an electronic device 210, another wearable device 220, and a server 230. In an embodiment, at least one (e.g., the other wearable device 220 or the server 230) of the above devices may be omitted from the exercise management system 200, or one or more other devices (e.g., an exclusive controller device of the wearable device 100) may be added thereto.

In an embodiment, the wearable device 100 may be worn on the body of the user in a walking assistance mode to assist a motion of the user. For example, the wearable device 100 may be worn on legs of the user to help the user in walking by generating an assistance force for assisting a leg motion of the user.

In an embodiment, the wearable device 100 may generate a resistance force for hindering a body motion of the user or an assistance force for assisting a body motion of the user and apply the generated resistance force or assistance force to the body of the user to enhance the exercise effect of the user in an exercise assistance mode. In the exercise assistance mode, the user may select, through the electronic device 210, an exercise program (e.g., squat, split lunge, dumbbell squat, lunge and knee up, stretching, or the like) to perform using the wearable device 100 and/or an exercise intensity to be applied to the wearable device 100. The wearable device 100 may control a driving module of the wearable device 100 according to the exercise program selected by the user and obtain sensor data including motion information of the user through a sensor module. The wearable device 100 may adjust the strength of the resistance force or assistance force applied to the user according to the exercise intensity selected by the user. For example, the wearable device 100 may control the driving module to generate a resistance force corresponding to the exercise intensity selected by the user.

In an embodiment, the wearable device 100 may be used to measure a physical ability of the user by interworking with the electronic device 210. The wearable device 100 may operate in a physical ability measurement mode, which is a mode for measuring the physical ability of the user, under a control of the electronic device 210, and may transmit sensor data obtained by a motion of the user in the physical ability measurement mode to the electronic device 210. The electronic device 210 may estimate the physical ability of the user by analyzing the sensor data received from the wearable device 100.

The electronic device 210 may communicate with the wearable device 100 and may remotely control the wearable device 100 or provide the user with state information about a state (e.g., a booting state, a charging state, a sensing state, or an error state) of the wearable device 100. The electronic device 210 may receive sensor data obtained by a sensor of the wearable device 100 from the wearable device 100 and estimate the physical ability of the user or an exercise result based on the received sensor data. In an embodiment, when the user exercises wearing the wearable device 100, the wearable device 100 may obtain sensor data including motion information of the user using sensors and transmit the obtained sensor data to the electronic device 210. The electronic device 210 may extract a motion value of the user from the sensor data and evaluate an exercise posture of the user based on the extracted motion value. The electronic device 210 may provide the user with an exercise posture measured value and exercise posture evaluation information related to the exercise posture of the user through a graphical user interface (GUI).

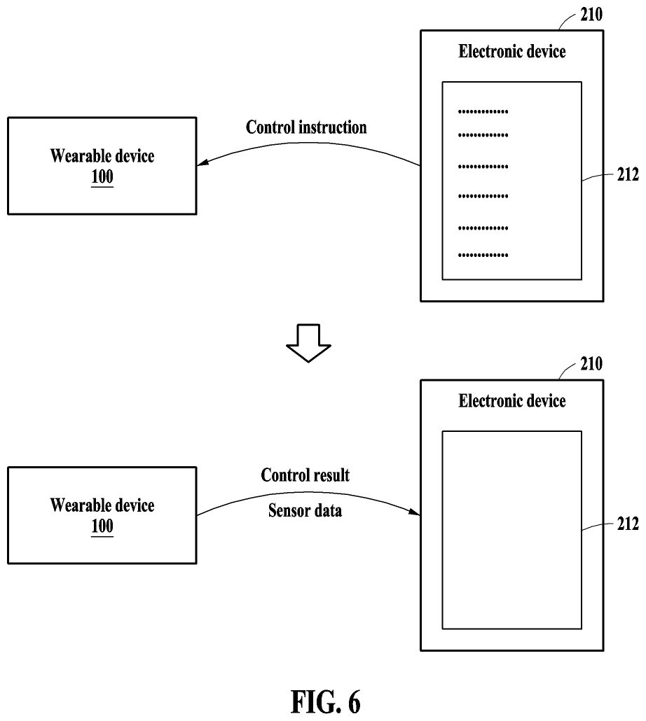

In an embodiment, the electronic device 210 may execute a program (e.g., an application) configured to control the wearable device 100, and the user may adjust an operation or a set value of the wearable device 100 (e.g., the magnitude of torque output from a driving module (e.g., driving modules 35 and 45 of FIG. 3), the volume of audio output from a sound output module (e.g., a sound output module 550 of FIGS. 6A and 5B), or the brightness of a lighting unit (e.g., a lighting unit 85 of FIG. 3)) through the corresponding program. The program executed by the electronic device 210 may provide a GUI for interaction with the user. The electronic device 210 may be a device in various forms. For example, the electronic device 210 may include, but is not limited to, a portable communication device (e.g., a smartphone), a computer device, an access point, a portable multimedia device, or a home appliance device (e.g., a television, an audio device, a projector device).

According to an embodiment, the electronic device 210 may be connected to the server 230 using short-range wireless communication or cellular communication. The server 230 may receive user profile information of the user who uses the wearable device 100 from the electronic device 210 and store and manage the received user profile information. The user profile information may include, for example, information about at least one of the name, age, gender, height, weight, or body mass index (BMI). The server 230 may receive exercise history information about an exercise performed by the user from the electronic device 210 and store and manage the received exercise history information. The server 230 may provide the electronic device 210 with various exercise programs or physical ability measurement programs that may be provided to the user.

According to an embodiment, the wearable device 100 and/or the electronic device 210 may be connected to the other wearable device 220. The other wearable device 220 may include, for example, wireless earphones 222, a smartwatch 224, or smart glasses 226, but is not limited thereto. In an embodiment, the smartwatch 224 may measure a biosignal including heart rate information of the user and transmit the measured biosignal to the electronic device 210 and/or the wearable device 100. The electronic device 210 may estimate the heart rate information (e.g., a current heart rate, a maximum heart rate, and an average heart rate) of the user based on the biosignal received from the smartwatch 224 and provide the estimated heart rate information to the user.

In an embodiment, the exercise result information, physical ability information, and/or exercise posture evaluation information evaluated by the electronic device 210 may be transmitted to the other wearable device 220 and provided to the user through the other wearable device 220. State information of the wearable device 100 may also be transmitted to the other wearable device 220 and provided to the user through the other wearable device 220. In an embodiment, the wearable device 100, the electronic device 210, and the other wearable device 220 may be connected to each other through wireless communication (e.g., Bluetooth communication or wireless-fidelity (Wi-Fi) communication).

In an embodiment, the wearable device 100 may provide (or output) feedback (e.g., visual feedback, auditory feedback, or haptic feedback) corresponding to a state of the wearable device 100 according to a control signal received from the electronic device 210. For example, the wearable device 100 may provide visual feedback through the lighting unit (e.g., the lighting unit 85 of FIG. 3) and provide auditory feedback through the sound output module (e.g., the sound output module 550 of FIGS. 5A and 5B). The wearable device 100 may include a haptic module and provide haptic feedback in the form of vibration to the body of the user through the haptic module. The electronic device 210 may also provide (or output) feedback (e.g., visual feedback, auditory feedback, or haptic feedback) corresponding to the state of the wearable device 100.

In an embodiment, the electronic device 210 may present a personalized exercise goal to the user in the exercise assistance mode. The personalized exercise goal may include respective target amounts of exercise for exercise types (e.g., strength exercise, balance exercise, and aerobic exercise) desired by the user, determined by the electronic device 210 and/or the server 230. When the server 230 determines a target amount of exercise, the server 230 may transmit information about the determined target amount of exercise to the electronic device 210. The electronic device 210 may personalize and present the target amounts of exercise for the exercise types, such as strength exercise, aerobic exercise, and balance exercise, according to a desired exercise program (e.g., squat, split lunge, or a lunge and knee up) and/or physical characteristics (e.g., the age, height, weight, and BMI) of the user. The electronic device 210 may display a GUI screen displaying the target amounts of exercise for the respective exercise types on a display.

In an embodiment, the electronic device 210 and/or the server 230 may include a database in which information about a plurality of exercise programs to be provided to the user through the wearable device 100 is stored. To achieve an exercise goal of the user, the electronic device 210 and/or the server 230 may recommend an exercise program suitable for the user. The exercise goal may include, for example, at least one of muscle strength improvement, physical strength improvement, cardiovascular endurance improvement, core stability improvement, flexibility improvement, or symmetry improvement. The electronic device 210 and/or the server 230 may store and manage the exercise program performed by the user, results of performing the exercise program, and the like.

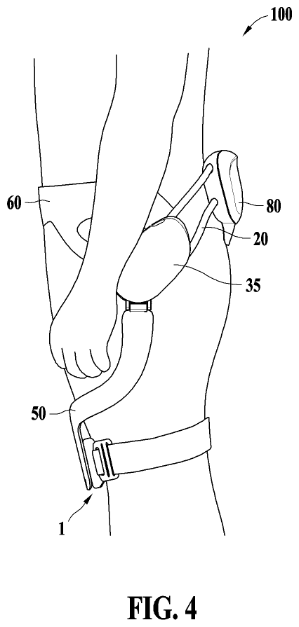

FIG. 3 is a rear schematic view of a wearable device, according to an embodiment. FIG. 4 is a left side view of a wearable device, according to an embodiment.

Referring to FIGS. 3 and 4, the wearable device 100 according to an embodiment may include the base body 80, the waist support frame 20, the driving modules 35 and 45, the leg support frames 50 and 55, thigh fastening portions 1 and 2, and a waist fastening portion 60. The base body 80 may include the lighting unit 85. In an embodiment, at least one (e.g., the lighting unit 85) of the above components may be omitted from the wearable device 100, or one or more other components (e.g., a haptic module) may be added to the wearable device 100.

The base body 80 may be disposed on a lumbar region of a user while the user is wearing the wearable device 100. The base body 80 may be mounted on the lumbar region of the user to provide a cushioning feeling to the lower back of the user and may support the lower back of the user. The base body 80 may be hung on a hip region (an area of the hips) of the user to prevent the wearable device 100 from being separated downward due to gravity while the user is wearing the wearable device 100. The base body 80 may distribute a portion of a weight of the wearable device 100 to the lower back of the user while the user is wearing the wearable device 100. The base body 80 may be connected, directly or indirectly, to the waist support frame 20. Waist support frame connecting elements (not shown) to be connected to the waist support frame 20 may be provided at both end portions of the base body 80.

In an embodiment, the lighting unit 85 may be arranged on an outer side of the base body 80. The lighting unit 85 may include a light source (e.g., a light-emitting diode (LED)). The lighting unit 85 may emit light under a control of a control module (not shown) (e.g., the control module 510 of FIGS. 5A and 5B). According to an embodiment, the control module may control the lighting unit 85 to provide (or output) visual feedback corresponding to the state of the wearable device 100 to the user through the lighting unit 85.

The waist support frame 20 may extend from both end portions of the base body 80. The lumbar region of the user may be accommodated inside the waist support frame 20. The waist support frame 20 may include at least one rigid body beam. Each beam may be in a curved shape having a preset curvature to enclose the lumbar region of the user. The waist fastening portion 60 may be connected, directly or indirectly, to an end portion of the waist support frame 20. The driving modules 35 and 45 may be connected, directly or indirectly, to the waist support frame 20.

In an embodiment, the control module, an IMU (not shown) (e.g., the IMU 135 of FIG. 1 or an IMU 522 of FIG. 5B), a communication module (not shown) (e.g., a communication module 516 of FIGS. 5A and 5B), and a battery (not shown) may be arranged inside the base body 80. The base body 80 may protect the control module, the IMU, the communication module, and the battery. The control module may generate a control signal for controlling an operation of the wearable device 100. The control module may include a control circuit including a processor configured to control actuators of the driving modules 35 and 45 and a memory. The control module may further include a power supply module (not shown) to supply power from a battery to each of the components of the wearable device 100.

In an embodiment, the wearable device 100 may include a sensor module (not shown) (e.g., the sensor module 520 of FIG. 5A) configured to obtain sensor data from at least one sensor. The sensor module may obtain sensor data that changes according to a motion of the user. In an embodiment, the sensor module may obtain sensor data including motion information of the user and/or motion information of the components of the wearable device 100. The sensor module may include, for example, an IMU (e.g., the IMU 135 of FIG. 1 or the IMU 522 of FIG. 5B) configured to measure an upper body motion value of the user or a motion value of the waist support frame 20 and an angle sensor (e.g., the angle sensor 125 of FIG. 1 or a first angle sensor 520 and a second angle sensor 520-1 of FIG. 5B) configured to measure a hip joint angle value of the user or a motion value of the leg support frames 50 and 55, but is not limited thereto. For example, the sensor module may further include at least one of a position sensor, a temperature sensor, a biosignal sensor, and a proximity sensor.

The waist fastening portion 60 may be connected, directly or indirectly, to the waist support frame 20 to fasten the waist support frame 20 to a waist of the user. The waist fastening portion 60 may include, for example, a pair of belts.

The driving modules 35 and 45 may generate an external force (or torque) to be applied to the body of the user based on the control signal generated by the control module. For example, the driving modules 35 and 45 may generate an assistance force or resistance force to be applied to legs of the user. In an embodiment, the driving modules 35 and 45 may include a first driving module 45 disposed in a position corresponding to a position of a right hip joint of the user, and a second driving module 35 disposed in a position corresponding to a position of a left hip joint of the user. The first driving module 45 may include a first actuator and a first joint member, and the second driving module 35 may include a second actuator and a second joint member. The first actuator may provide power to be transmitted to the first joint member, and the second actuator may provide power to be transmitted to the second joint member. The first actuator and the second actuator may each include a motor configured to generate power (or a torque) by receiving electric power from the battery. When the motor receives power and is driven, the motor may generate a force (an assistance force) for assisting a body motion of the user or a force (a resistance force) for hindering a body motion of the user. In an embodiment, the control module may adjust the magnitude or direction of a force generated by the motor by adjusting a voltage or a current supplied to the motor.

In an embodiment, the first joint member and the second joint member may receive power from the first actuator and the second actuator, respectively, and may apply an external force to the body of the user based on the received power. The first joint member and the second joint member may be arranged at positions corresponding to joint portions of the user, respectively. One side of the first joint member may be connected, directly or indirectly, to the first actuator, and the other side of the first joint member may be connected, directly or indirectly, to a first leg support frame 55. The first joint member may be rotated by the power received from the first actuator. An encoder or a Hall sensor that may operate as an angle sensor configured to measure the rotational angle of the first joint member (corresponding to the joint angle of the user) may be arranged on one side of the first joint member. One side of the second joint member may be connected, directly or indirectly, to the second actuator, and the other side of the second joint member may be connected, directly or indirectly, to a second leg support frame 50. The second joint member may rotate by the power relayed from the second actuator. An encoder or a Hall sensor that may operate as an angle sensor configured to measure a rotation angle of the second joint member may be arranged on one side of the second joint member.

In an embodiment, the first actuator may be arranged in a lateral direction of the first joint member, and the second actuator may be arranged in a lateral direction of the second joint member. A rotation axis of the first actuator and a rotation axis of the first joint member may be spaced apart from each other, and a rotation axis of the second actuator and a rotation axis of the second joint member may also be spaced apart from each other. However, embodiments are not limited thereto, and an actuator and a joint member may share a rotation axis. In an embodiment, each actuator may be spaced apart from a corresponding joint member. In this case, the driving module 35, 45 may further include a power transmission module (not shown) configured to transmit power from the actuator to the joint member. The power transmission module may be a rotary body, such as a gear, or a longitudinal member, such as a wire, a cable, a string, a spring, a belt, or a chain. However, the scope of the embodiment is not limited by a positional relationship between an actuator and a joint member and a power transmission structure described above.

In an embodiment, the leg support frame 50, 55 may support a leg (e.g., a thigh) of the user when the wearable device 100 is worn on the leg of the user. For example, the leg support frame 50, 55 may transmit power (a torque) generated by the driving module 35, 45 to the thigh of the user, and the power may function as an external force to be applied to a motion of the leg of the user. As one end portion of the leg support frame 50, 55 is connected to a joint member to rotate and the other end portion of the leg support frame 50, 55 is connected to the thigh fastening portion 1, 2, the leg support frame 50, 55 may transmit the power generated by the driving module 35, 45 to the thigh of the user while supporting the thigh of the user. For example, the leg support frame 50, 55 may push or pull the thigh of the user. The leg support frame 50, 55 may extend in a longitudinal direction of the thigh of the user. The leg support frame 50, 55 may be folded to wrap around at least a portion of a thigh circumference of the user. The leg support frames 50 and 55 may include a first leg support frame 55 configured to support a right leg of the user, and a second leg support frame 50 configured to support a left leg of the user.

The thigh fastening portion 1, 2 may be connected, directly or indirectly, to the leg support frame 50, 55 and may fasten the leg support frame 50, 55 to the thighs. The thigh fastening portions 1, 2 may include a first thigh fastening portion 2 configured to fasten the first leg support frame 55 to a right thigh of the user, and a second thigh fastening portion 1 configured to fasten the second leg support frame 50 to a left thigh of the user.

In an embodiment, the first thigh fastening portion 2 may include a first cover, a first fastening frame, and a first strap, and the second thigh fastening portion 1 may include a second cover, a second fastening frame, and a second strap. The first cover and the second cover may apply torques generated by the driving modules 35 and 45 to the thighs of the user. The first cover and the second cover may be arranged on one sides of the thighs of the user to push or pull the thighs of the user. For example, the first cover and the second cover may be arranged on front surfaces of the thighs of the user. The first cover and the second cover may be arranged in circumferential directions of the thighs of the user. The first cover and the second cover may extend to both sides from the other end portions of the leg support frames 50 and 55 and may include curved surfaces corresponding to the thighs of the user. One end of the first cover and one end of the second cover may be connected, directly or indirectly, to the fastening frames, and the other ends thereof may be connected, directly or indirectly, to the straps.

The first fastening frame and the second fastening frame may be arranged, for example, to surround at least some portions of the circumferences of the thighs of the user, thereby preventing the thighs of the user from being separated from the leg support frames 50 and 55. The first fastening frame may have a fastening structure that connects the first cover and the first strap, and the second fastening frame may have a fastening structure that connects the second cover and the second strap.

The first strap may enclose the remaining portion of the circumference of the right thigh of the user that is not covered by the first cover and the first fastening frame, and the second strap may enclose the remaining portion of the circumference of the left thigh of the user that is not covered by the second cover and the second fastening frame. The first strap and the second strap may include, for example, an elastic material (e.g., a band).

FIGS. 5A and 5B are diagrams illustrating a configuration of a control system of a wearable device, according to an embodiment.

Referring to FIG. 5A, the wearable device 100 may be controlled by a control system 500. The control system 500 may include the control module 510, the communication module 516, the sensor module 520, a driving module 530, an input module 540, and the sound output module 550. In an embodiment, at least one (e.g., the sound output module 550) of the above components may be omitted from the control system 500, or one or more other components (e.g., a haptic module) may be added to the control system 500.

The driving module 530 may include a motor 534 configured to generate power (e.g., torque), and a motor driver circuit 532 to drive the motor 534. Although FIG. 5A illustrates the driving module 530 including one motor driver circuit 532 and one motor 534, the example of FIG. 5A is merely an example. Referring to FIG. 5B, a control system 500-1 may include a plurality of (e.g., two or more) motor driver circuits 532 and 532-1 and a plurality of (e.g., two or more) motors 534 and 534-1. The driving module 530 including the motor driver circuit 532 and the motor 534 may correspond to the first driving module 45 of FIG. 3, and a driving module 530-1 including the motor driver circuit 532-1 and the motor 534-1 may correspond to the second driving module 35 of FIG. 3. The following descriptions of the motor driver circuit 532 and the motor 534 may also be respectively applicable to the motor driver circuit 532-1 and the motor 534-1 illustrated in FIG. 5B.

Referring back to FIG. 5A, the sensor module 520 may include a sensor circuit including at least one sensor. The sensor module 520 may obtain sensor data including motion information of a user or motion information of the wearable device 100. The sensor module 520 may transmit the obtained sensor data to the control module 510. The sensor module 520 may include an IMU 522 and an angle sensor (e.g., the first angle sensor 520 and the second angle sensor 520-1) as illustrated in FIG. 5B. The IMU 522 may measure an upper body motion value of the user. For example, the IMU 522 may sense X-axis, Y-axis, and Z-axis accelerations and X-axis, Y-axis, and Z-axis angular velocities according to a motion of the user. The IMU 522 may be used to measure, for example, at least one of a forward and backward tilt, a left and right tilt, or a rotation of the body of the user. In addition, the IMU 522 may obtain motion values (e.g., acceleration values and angular velocity values) of a waist support frame (e.g., the waist support frame 20 of FIG. 3) of the wearable device. The motion values of the waist support frame 100 may correspond to upper body motion values of the user.

The angle sensor may measure a hip joint angle value according to a motion of a leg of the user. Sensor data that may be measured by the angle sensor may include, for example, a hip joint angle value of a right leg, a hip joint angle value of a left leg, and information on a motion direction of a leg. For example, the first angle sensor 520 of FIG. 5B may obtain the hip joint angle value of the right leg of the user, and the second angle sensor 520-1 may obtain the hip joint angle value of the left leg of the user. For example, the first angle sensor 520 and the second angle sensor 520-1 may each include, for example, an encoder and/or a hall sensor. In addition, the angle sensor may obtain a motion value of a leg support frame of the wearable device. For example, the first angle sensor 520 may obtain a motion value of the first leg support frame 55 and the second angle sensor 520-1 may obtain a motion value of the second leg support frame 50. The motion values of the leg support frame may correspond to the hip joint angle values.

In an embodiment, the sensor module 520 may further include at least one of a position sensor configured to obtain a position value of the wearable device 100, a proximity sensor configured to sense the proximity of an object, a biosignal sensor configured to detect a biosignal of the user, or a temperature sensor configured to measure an ambient temperature.

The input module 540 may receive a command or data to be used by another component (e.g., the processor 512) of the wearable device 100 from the outside (e.g., a user) of the wearable device 100. The input module 540 may include an input component circuit. The input module 540 may include, for example, a key (e.g., a button) or a touch screen.

The sound output module 550 may output a sound signal to the outside of the wearable device 100. The sound output module 550 may provide auditory feedback to the user. For example, the sound output module 550 may include a speaker configured to play back a guiding sound signal (e.g., an operation start sound, an operation error alarm, or an exercise start alarm), music content, or a guiding voice for auditorily informing predetermined information (e.g., exercise result information or exercise posture evaluation information).

In an embodiment, the control system 500 may further include a battery (not shown) configured to supply power to each component of the wearable device. The wearable apparatus may convert the power of the battery into power suitable for an operating voltage of each component of the wearable apparatus and supply the converted power to each component.

The driving module 530 may generate an external force to be applied to the leg of the user by control of the control module 510. The driving module 530 may generate a torque to be applied to the legs of the user based on a control signal generated by the control module 510. The control module 510 may transmit the control signal to the motor driver circuit 532. The motor driver circuit 532 may control the operation of the motor 534 by generating a current signal (or voltage signal) corresponding to the control signal and supplying the generated current signal to the motor 534. In some cases, the current signal may not be supplied to the motor 534. When the motor 534 is supplied with the current signal and driven, the motor 534 may generate a torque for an assistance force for assisting a leg motion of the user or a resistance force for hindering a leg motion of the user.

The control module 510 may control the overall operation of the wearable apparatus and may generate a control signal for controlling each component (e.g., the communication module 516 or the driving module 530). The control module 510 may include a processor 512 and a memory 514.

The processor 512 may execute, for example, software to control at least one other component (e.g., a hardware or software component) of the wearable apparatus connected to the processor 512 and may perform various types of data processing or operations. The software may include an application for providing a GUI. According to an embodiment, as at least a part of data processing or computation, the processor 512 may store instructions or data received from another component (e.g., the communication module 516) in the memory 514, may process the instructions or the data stored in the memory 514, and may store result data in the memory 514. According to an embodiment, the processor 512 may include a main processor (e.g., a central processing unit (CPU) or an application processor (AP)), or an auxiliary processor (e.g., a graphics processing unit (GPU), a neural processing unit (NPU), an image signal processor (ISP), a sensor hub processor, or a communication processor (CP)) that is operable independently of or in conjunction with the main processor. The auxiliary processor may be implemented separately from the main processor or as a part of the main processor.

Each “processor” herein includes processing circuitry, and/or may include multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The memory 514 may store a variety of data used by at least one component (e.g., the processor 512) of the control module 510. The variety of data may include, for example, software, sensor data, input data or output data for instructions related thereto. The memory 514 may include a volatile memory or a non-volatile memory (e.g., random-access memory (RAM), dynamic RAM (DRAM), or static RAM (SRAM)).

The communication module 516 may support establishing a direct (e.g., wired) communication channel or a wireless communication channel between the control module 510 and another component of the wearable device 100 or an external electronic device (e.g., the electronic device 210 or the other wearable device 220 of FIG. 2) and performing communication via the established communication channel. The communication module 516 may include a communication circuit configured to perform a communication function. For example, the communication module 516 may receive a control signal from an electronic device (e.g., the electronic device 210) and transmit the sensor data obtained by the sensor module 520 to the electronic device. According to an embodiment, the communication module 516 may include one or more CPs (not shown) that are operable independently of the processor 512 and that support direct (e.g., wired) communication or wireless communication. According to an embodiment, the communication module 516 may include a wireless communication module (e.g., a cellular communication module, a short-range wireless communication module, or a global navigation satellite system (GNSS) communication module), and/or a wired communication module. A corresponding one of the above communication modules may communicate with another component of the wearable device 100 and/or an external electronic device via a short-range communication network, such as Bluetooth™, Wi-Fi, or infrared data association (IrDA), or a long-range communication network, such as a legacy cellular network, a fifth generation (5G) network, a next-generation communication network, the Internet, or a computer network (e.g., a local area network (LAN) or a wide region network (WAN)).

In an embodiment, the control system 500, 500-1 may further include a haptic module (not shown). The haptic module may provide haptic feedback to the user under the control of the processor 512. The haptic module may convert an electrical signal into a mechanical stimulus (e.g., a vibration or a movement) or an electrical stimulus which may be recognized by a user via his or her tactile sensation or kinesthetic sensation. The haptic module may include a motor, a piezoelectric element, or an electrical stimulation device. In an embodiment, the haptic module may be positioned in at least one of the base body (e.g., the base body 80), the first thigh fastening portion 2, or the second thigh fastening portion 1.

FIG. 6 is a diagram illustrating an interaction between a wearable device and an electronic device, according to an embodiment.

Referring to FIG. 6, the wearable device 100 may communicate with the electronic device 210. For example, the electronic device 210 may be a user terminal of a user who uses the wearable device 100 or a controller device dedicated to the wearable device 100. In an embodiment, the wearable device 100 and the electronic device 210 may be connected to each other through short-range wireless communication (e.g., Bluetooth communication or Wi-Fi communication).

In an embodiment, the electronic device 210 may check a state of the wearable device 100 or execute an application to control or operate the wearable device 100. A screen of a UI may be displayed to control an operation of the wearable device 100 or determine an operation mode of the wearable device 100 on a display 212 of the electronic device 210 through the execution of the application. The UI may be, for example, a GUI.

In an embodiment, the user may input an instruction for controlling the operation of the wearable device 100 (e.g., an execution instruction to a walking assistance mode, an exercise assistance mode, or a physical ability measurement mode) or change settings of the wearable device 100 through a GUI screen on the display 212 of the electronic device 210. The electronic device 210 may generate a control instruction (or control signal) corresponding to an operation control instruction or a setting change instruction input by the user and transmit the generated control instruction to the wearable device 100. The wearable device 100 may operate according to the received control instruction and may transmit a control result according to the received control instruction and/or sensor data sensed by a sensor module of the wearable device 100 to the electronic device 210. The electronic device 210 may provide the user with result information (e.g., walking ability information, exercise ability information, or exercise posture evaluation information) derived by analyzing the control result and/or the sensor data through the GUI screen.

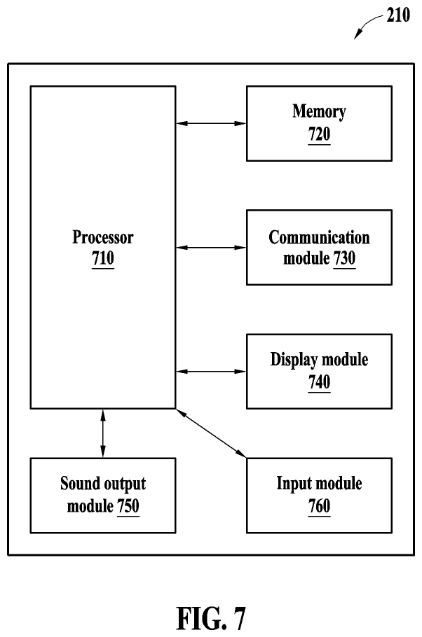

FIG. 7 is a diagram illustrating a configuration of an electronic device, according to an embodiment.

Referring to FIG. 7, the electronic device 210 may include a processor 710, a memory 720, a communication module 730, a display module 740, a sound output module 750, and an input module 760. In an embodiment, at least one (e.g., the sound output module 750) of the above components may be omitted from the electronic device 210, or one or more other components (e.g., a sensor module and a battery) may be added to the electronic device 210.

The processor 710 may control at least one other component (e.g., a hardware or software component) of the electronic device 210, and may perform a variety of data processing or computation. According to an embodiment, as at least a part of data processing or computation, the processor 710 may store instructions or data received from another component (e.g., the communication module 730) in the memory 720, process the instructions or data stored in the memory 720, and store result data in the memory 720.

According to an embodiment, the processor 710 may include a main processor (e.g., a CPU or an AP) or an auxiliary processor (e.g., a GPU, an NPU, an ISP, a sensor hub processor, or a CP) that is operable independently of or in conjunction with the main processor.

The memory 720 may store a variety of data used by at least one component (e.g., the processor 710 or the communication module 730) of the electronic device 210. The data may include, for example, a program (e.g., an application), and input data or output data for a command related thereto. The memory 720 may include at least one instruction executable by the processor 710. The memory 720 may include, for example, a volatile memory or a non-volatile memory.

The communication module 730 may support establishing a direct (e.g., wired) communication channel or a wireless communication channel between the electronic device 210 and another electronic device (e.g., the wearable device 100, the other wearable device 220, or the server 230) and performing communication via the established communication channel. The communication module 730 may include a communication circuit configured to perform a communication function. The communication module 730 may include one or more CPs that are operable independently of the processor 710 (e.g., an AP) and that support direct (e.g., wired) communication or wireless communication. According to an embodiment, the communication module 290 may include a wireless communication module configured to perform wireless communication (e.g., a Bluetooth communication module, a cellular communication module, a Wi-Fi communication module, or a GNSS communication module) or a wired communication module (e.g., a LAN communication module or a power line communication (PLC) module). For example, the communication module 730 may transmit a control instruction to the wearable device 100 and receive, from the wearable device 100, at least one of sensor data including body motion information of the user who is wearing the wearable device 100, state data of the wearable device 100, or control result data corresponding to the control instruction.

The display module 740 may visually provide information to the outside (e.g., a user) of the electronic device 210. The display module 740 may include, for example, a liquid-crystal display (LCD) or organic LED (OLED) display, a hologram device, or a projector device. The display module 740 may further include a control circuit configured to control the driving of a display. In an embodiment, the display module 740 may include a touch sensor adapted to sense a touch, or a pressure sensor adapted to measure an intensity of a force incurred by the touch.

The sound output module 750 may output a sound signal to the outside of the electronic device 210. The sound output module 750 may include a guide sound signal (e.g., a driving start sound or an operation error notification sound) based on a state of the wearable device 100 and a speaker for playing musical content or a guide voice. When it is determined that the wearable device 100 is not properly worn on the body of the user, the sound output module 750 may output a guiding voice for informing the user is wearing the wearable device 100 abnormally or for guiding the user to wear the wearable device 100 normally. The sound output module 750 may output, for example, a guiding voice corresponding to exercise evaluation information or exercise result information obtained by evaluating an exercise of the user.

The input module 760 may receive a command or data to be used by another component (e.g., the processor 710) of the electronic device 210, from the outside (e.g., a user) of the electronic device 210. The input module 760 may include an input component circuit and may receive a user input. The input module 760 may include, for example, a key (e.g., a button) or a touch screen.

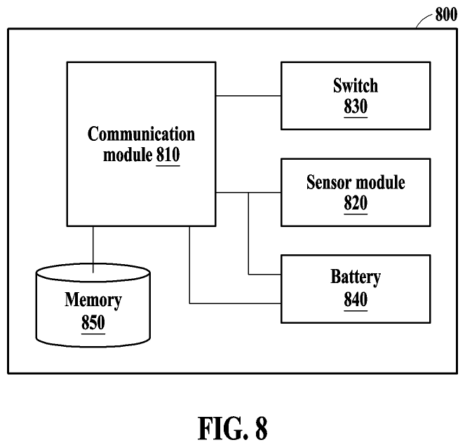

FIG. 8 is a diagram illustrating a configuration of an electronic device for detecting a connection of a fastening frame, according to an embodiment.

According to an embodiment, each of the thigh fastening portions 1 and 2 described above with reference to FIG. 3 may further include an electronic device 800. For example, the electronic device 800 may be included in a housing corresponding to a cover of a thigh fastening portion (e.g., the first thigh fastening portion 2 or the second thigh fastening portion 1). One end of a fastening strap may be connected to the housing, while the other end of the fastening strap may be connected to the fastening frame. When the fastening strap is connected to the housing, the fastening strap may be disposed to wrap around at least a portion of a thigh of a user, thereby preventing the thigh of the user from disengaging from a leg support frame. The fastening frame may have a fastening structure connecting the cover to the strap.

According to an embodiment, the housing of the electronic device 800 may be mechanically connected to the wearable device 100 (e.g., the first leg support frame 55 or the second leg support frame 50 of FIGS. 3 and 4) described above with reference to FIG. 1.

According to an embodiment, the electronic device 800 may include a communication module 810, a sensor module 820, a switch 830, a battery 840, and a memory 850. For example, the electronic device 800 may detect, based on information sensed by the sensor module 820, whether the fastening frame is connected to at least a portion of the housing of the electronic device 800.

The wearable device 100 described above with reference to FIGS. 1 to 6 may need to be tightly attached to the body of the user to assist a motion of the user. For example, when the first thigh fastening portion 2 of the wearable device 100 is not tightly attached to the thigh of the user (i.e., the wearable device is not worn completely), malfunction of the wearable device 100 may occur. According to an embodiment, the control of the wearable device 100 may be performed based on whether the fastening frame of the wearable device is normally connected to the cover. For example, the electronic device 800 located on the cover of the wearable device 100 may determine whether the fastening frame is connected to at least a portion of the housing. The wearable device 100 may perform the control of the wearable device 100, based on the determination of the electronic device 800.

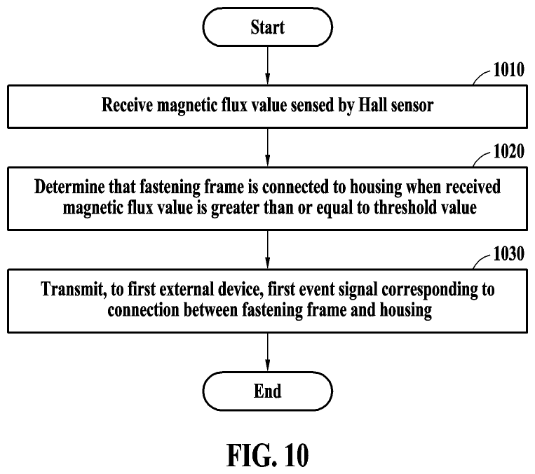

According to an embodiment, the description of the communication module 810 may be replaced with the description of the communication module 730 described above with reference to FIG. 7, and thus, any repeated description related thereto is omitted. The communication module 810 may include at least one processor (e.g., a communication processor) that controls the communication module 810 and/or the electronic device 800. The operations of the communication module 810 are described in detail with reference to FIGS. 10 to 14.

According to an embodiment, the sensor module 820 may generate sensing information by using at least one sensor. For example, the sensor module 820 may include a Hall sensor. The Hall sensor may determine a magnetic flux value by sensing a magnetic flux that appears around the Hall sensor. For example, the sensor module 820 may include an IMU.

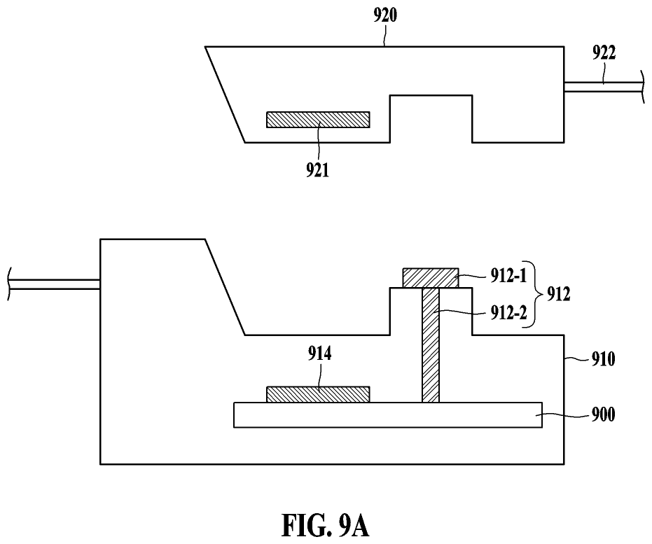

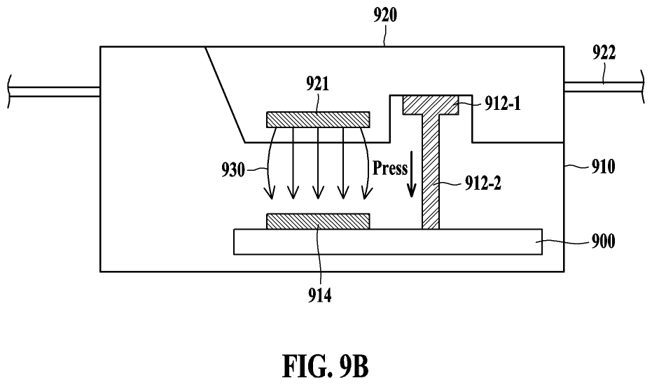

According to an embodiment, the switch 830 may be a switch that powers on the electronic device 800. For example, the switch 830 may be a mechanical switch. For example, when the switch 830 is pressed by an external force, the electronic device 800 (or the communication module 810) may be powered on. The switch 830 may be pressed when the fastening frame is connected (or engaged or fastened) to at least a portion of the housing of the electronic device 800. For example, the switch 830 may have a mechanical structure that is pressed by the fastening frame when the fastening frame is connected to at least a portion of the housing. Hereinafter, with reference to FIGS. 9A and 9B, a case in which the switch 830 is pressed by the fastening frame is described in detail.

According to an embodiment, the battery 840 may supply power to the electronic device 800. For example, the battery 840 may be a rechargeable battery. For example, the battery 840 may be a dry cell battery (e.g., a coin cell battery or a button cell battery). For example, when a circuit of the electronic device 800 is connected, directly or indirectly, to the battery 840 by the switch 830, the battery 840 may supply power to the circuit of the electronic device 800.

The memory 850 may comprise one or more storage media storing instructions. The instructions, when executed by the at least one processor (e.g., a communication processor) individually or collectively, may cause the electronic device 800 to perform operations described herein. For example, the instructions, when executed by the at least one processor (e.g., a communication processor) individually or collectively, may cause the electronic device 800 to perform at least portion of operations 1010 to 1030, 1110 and 1120, 1210 and 1220, 1310 and 1320, 1410 to 1430, 1510 to 1530, 1610 and 1620, 1710 to 1730.

According to an embodiment, the description of the memory 850 may be replaced with the description of the memory 514 described above with reference to FIG. 5 or the memory 720 described above with reference to FIG. 7, and thus, any repeated description thereof is omitted.

FIG. 9A is a diagram illustrating a non-connection state between a housing of an electronic device and a fastening frame, according to an embodiment, and FIG. 9B is a diagram illustrating a connection state between the housing of the electronic device and the fastening frame, according to an embodiment.

The diagrams of FIGS. 9A and 9B are cross-sectional views of a housing of an electronic device and a fastening frame, according to an embodiment.

According to an embodiment, a first portion 912-1 of a switch 912 (e.g., the switch 830 of FIG. 8) may be disposed to appear outside of a housing 910 of an electronic device (e.g., the electronic device 800 of FIG. 8). A second portion 912-2 of the switch 912, connected to the first portion 912-1, may be connected to a circuit 900 of the electronic device inside the housing 910, directly or indirectly. The circuit 900 of the electronic device may be configured on a printed circuit board (PCB). Although the first portion 912-1 is illustrated and described as being exposed to the outside, according to an embodiment, the first portion 912-1 may be positioned inside the housing 910.

According to an embodiment, a sensor module 914 (e.g., the sensor module 820 of FIG. 8) may be disposed in the housing 910 near the position of the switch 912. For example, the Hall sensor of the sensor module 914 may be placed around a coupling surface with the fastening frame 920 within the housing 910.

According to an embodiment, the fastening frame 920 may be connected, directly or indirectly, to a first end of a strap 922. A second end of the strap 922 may be connected, directly or indirectly, to at least a portion (e.g., the surface opposite to the coupling surface with the fastening frame 920) of the housing 910. For example, when the housing 910 is connected to the fastening frame 920, the strap 922 may wrap around at least a portion of the thigh of the user.

According to an embodiment, the fastening frame 920 may include a magnet 921, which is a magnetic body. The magnet 921 may generate a magnetic flux.

According to an embodiment, in a non-connection state between the housing 910 of the electronic device and the fastening frame 920, the switch 912 may not be pressed. When the switch 912 is not pressed, the electronic device is not powered on, so the Hall sensor of the sensor module 914 may not generate sensing information. For example, in a non-connection state between the housing 910 and the fastening frame 920, since the Hall sensor is powered off, the magnetic flux value of the magnet 921 may not be measured even when the magnet 921 is located around the Hall sensor.

According to an embodiment, in a connection state between the housing 910 of the electronic device and the fastening frame 920, the switch 912 may be pressed. For example, as the first portion 912-1 of the switch 912 is pressed by the fastening frame 920 and the first portion 912-1 is pressed, the second portion 912-2 may power on the electronic device. When the electronic device is powered on, power may be supplied to a communication module (e.g., the communication module 810 of FIG. 8) and the sensor module 914.

According to an embodiment, when power is supplied to the sensor module 914, the Hall sensor of the sensor module 914 may measure the value of the magnetic flux 930 generated by the magnet 921 of the fastening frame 920.

According to an embodiment, the communication module 810, comprising communication circuitry, may determine whether the housing 910 is connected to the fastening frame 920, based on the value of the magnetic flux 930. The communication module 810 may generate a first event signal when the housing 910 is connected to the fastening frame 920. The communication module 810 may transmit the first event signal to the wearable device 100. Hereinafter, a method in which the electronic device 800 generates and transmits the first event signal is described in detail with reference to FIGS. 10 to 14.

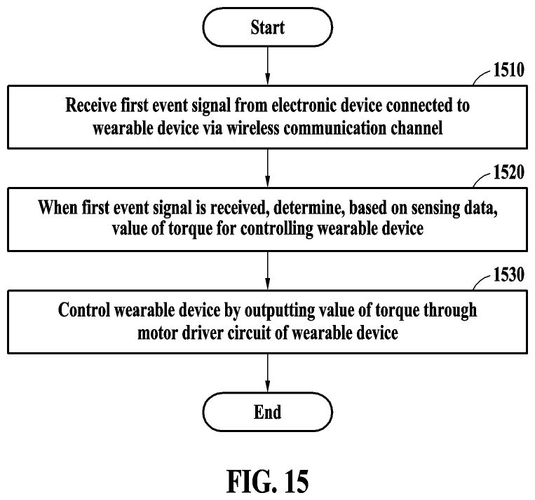

According to an embodiment, the wearable device 100 that receives the first event signal may determine that the body (e.g., thigh) of the user is tightly attached to the wearable device 100. The wearable device 100 may perform control to output a torque to the user when the body of the user is tightly attached to the wearable device 100. Hereinafter, a method of controlling the wearable device 100 based on the first event signal is described in detail with reference to FIGS. 15 to 17.

FIG. 10 is a flowchart of a method of detecting a connection of a fastening frame, performed by an electronic device, according to an embodiment.

Operations 1010 to 1030 may be performed by an electronic device (e.g., the electronic device 800 of FIG. 8). Operation 1010 may be performed when the electronic device is powered on. According to the example described above with reference to FIG. 9B, when a first portion 911 of the switch 830 is pressed, the electronic device may be powered on.

In operation 1010, the electronic device may receive a magnetic flux value sensed by a Hall sensor (e.g., the Hall sensor of the sensor module 820 of FIG. 8).

According to an embodiment, a magnet (e.g., the magnet 921 of FIG. 9) of a fastening frame (e.g., the fastening frame 920 of FIG. 9B) may generate a magnetic flux around the magnet. As the distance between the magnet and the Hall sensor decreases, the magnitude of the magnetic flux value measured by the Hall sensor may increase. For example, when the fastening frame is connected (or attached or fastened) to at least a portion of the housing (e.g., the housing 910 of FIG. 9B) of the electronic device, the Hall sensor and the magnet may be positioned closest to each other.

In operation 1020, the electronic device may determine that the fastening frame is connected to the housing when the received magnetic flux value is greater than or equal to a threshold value. For example, when the fastening frame is connected to at least a portion of the housing of the electronic device, the threshold value may be preset to be greater than a magnetic flux value measured by the Hall sensor disposed in the housing.

In operation 1030, when it is determined that the fastening frame is connected to the housing or the received magnetic flux value is greater than or equal to the threshold value, the electronic device may transmit, to the first external device, the first event signal corresponding to the connection between the fastening frame and the housing. For example, the first external device may be the wearable device 100 described above with reference to FIG. 1. For example, the first external device may be the electronic device 210, which is a mobile terminal described above with reference to FIG. 2.

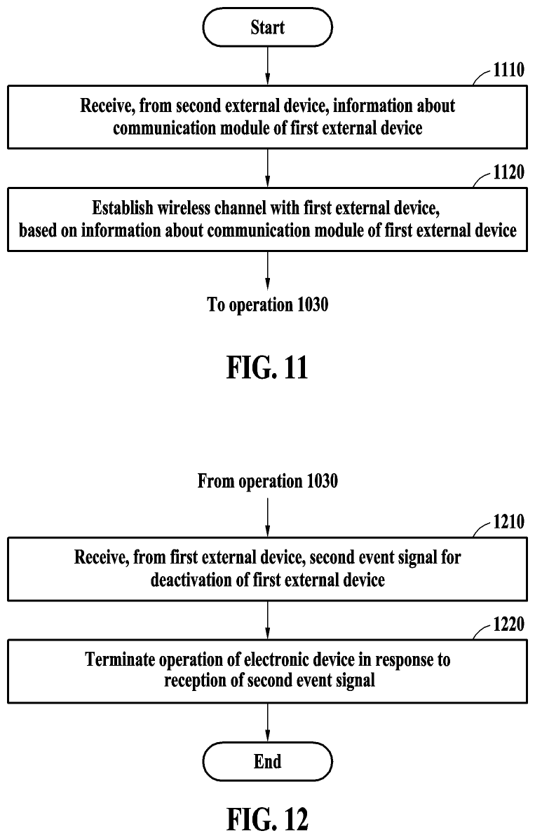

According to an embodiment, the electronic device may transmit the first event signal by using short-range wireless communication (e.g., Bluetooth low energy (BLE), near field communication (NFC), or Wi-Fi) and using a wireless channel established with the first external device. A method of establishing a wireless channel between an electronic device and a short-range wireless communication is described in detail below with reference to FIG. 11.

According to an embodiment, the wearable device 100 that directly receives the first event signal from the electronic device or indirectly receives the first event signal via the electronic device 210 may control an operation of the wearable device 100, based on the first event signal. For example, the wearable device 100 may adjust the value of a torque output by the wearable device 100, based on the first event signal. The operations of the wearable device 100 based on the first event signal are described below in detail with reference to FIGS. 15 to 17.

FIG. 11 is a flowchart of a method of establishing a wireless channel with a first external device, according to an embodiment.

According to an embodiment, operations 1110 and 1120 may be performed before operation 1030 described above with reference to FIG. 10 is performed. Operations 1110 and 1120 may be performed by an electronic device (e.g., the electronic device 800 of FIG. 8). Operation 1110 may be performed when the electronic device is powered on.

In operation 1110, the electronic device may receive, from a second external device (e.g., the electronic device 210 of FIG. 2), information about the communication module 516 of the first external device (e.g., the wearable device 100 of FIG. 5). For example, the information about the communication module of the first external device may include a media access control (MAC) address of the communication module. For example, the information about the communication module of the first external device may include the MAC address of the communication module of the first external device for the use of BLE.

According to an embodiment, the electronic device may receive, from the second external device via NFC, the information about the communication module of the first external device. For example, the information about the communication module of the first external device may be stored in the second external device in advance. A user may place the second external device in the vicinity of the electronic device to utilize NFC. The communication module of the electronic device may receive, from the second external device using NFC, the information about the communication module of the first external device

In operation 1120, the electronic device may establish a wireless channel with the first external device, based on the information about the communication module of the first external device. For example, the electronic device may propagate a beacon for BLE to the vicinity of the electronic device and establish, based on a response to the beacon, a wireless channel with the first external device. For example, the response to the beacon may include the MAC address of the communication module of the first external device.

According to an embodiment, when a wireless channel is established between the electronic device and the first external device, the electronic device may only perform communication with the first external device so as to transmit and receive a preset event signal. Data communication between the electronic device and the first external device may be minimized to reduce power consumed by the electronic device.

FIG. 12 is a flowchart of a method of terminating an operation of the electronic device, based on an event signal received from the first external device, according to an embodiment.

According to an embodiment, operations 1210 and 1220 may be performed after operation 1030 described above with reference to FIG. 10 is performed. Operations 1210 and 1220 may be performed by the electronic device (e.g., the electronic device 800 of FIG. 8).

In operation 1210, the electronic device may receive, from the first external device (e.g., the wearable device 100 of FIG. 1), a second event signal for deactivation of the first external device.

According to an embodiment, when the first external device is the wearable device 100 and the wearable device 100 enters a deactivation mode, the wearable device 100 may generate the second event signal for deactivation of the wearable device 100 and transmit the generated second event signal to the electronic device. The deactivation mode may be a mode or a state in which no torque is output by the wearable device 100. For example, when an input to power off the wearable device 100 is received, the mode of the wearable device 100 may be switched to the deactivation mode. For example, when an exercise mode set (or performed) on the wearable device 100 is terminated, the mode of the wearable device 100 may be switched to the deactivation mode.

In operation 1220, the electronic device may terminate the operation of the electronic device, in response to reception of the second event signal. For example, termination of the operation of the electronic device may be switching the operation mode of the electronic device to a sleep mode. For example, the electronic device may power off the electronic device when the second event signal is received. For example, to power off the electronic device, the connection between the circuit of the electronic device and a battery (e.g., the battery 840 of FIG. 8) may be disconnected.

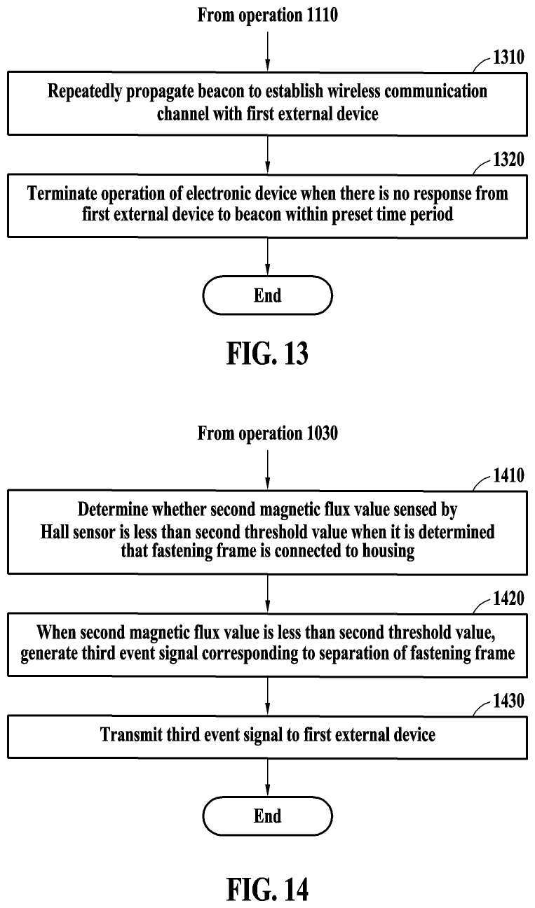

FIG. 13 is a flowchart of a method of terminating an operation of an electronic device when there is no response from a first external device to a beacon propagated by the electronic device, according to an embodiment.

According to an embodiment, operations 1310 and 1320 may be performed after operation 1110 described above with reference to FIG. 11 is performed. Operations 1310 and 1320 may be performed by the electronic device (e.g., the electronic device 800 of FIG. 8).

In operation 1310, the electronic device may propagate a beacon to establish a wireless communication channel with the first external device (e.g., the wearable device 100 of FIG. 1). For example, the electronic device may propagate the beacon repeatedly when no response to the beacon is received.

According to an embodiment, the value of transmission power for propagating the beacon may be a preset value. For example, since the distance between an antenna of the communication module of the electronic device and an antenna of the first external device may not exceed 1 meter (m), the value of the transmission power may be preset so that wireless communication may be performed within that distance.

In operation 1320, the electronic device may terminate the operation of the electronic device when there is no response from the first external device to the beacon within a preset time period. For example, the electronic device may terminate the operation of the electronic device when no response is received to the beacon that is repeatedly propagated for three minutes. Since the description of the termination of the operation may similarly apply to the description of operation 1220 described above with reference to FIG. 12, any repeated description thereof is omitted.

FIG. 14 is a flowchart of a method of transmitting, to a first external device, an event signal corresponding to separation of a fastening frame, according to an embodiment.

According to an embodiment, operations 1410 to 1430 may be performed after operation 1030 described above with reference to FIG. 10 is performed. Operations 1410 to 1430 may be performed by the electronic device (e.g., the electronic device 800 of FIG. 8).

In operation 1410, the electronic device may determine whether a second magnetic flux value sensed by the Hall sensor is less than a second threshold value when it is determined that the fastening frame is connected to the housing.

According to an embodiment, when the connection between the housing and the fastening frame is separated, the distance between the Hall sensor and the magnet may increase. As the distance between the Hall sensor and the magnet increases, the magnetic flux value sensed by the Hall sensor may decrease.

In operation 1420, when a second magnetic flux value is less than the second threshold value, the electronic device may generate a third event signal corresponding to separation of the fastening frame.

In operation 1430, the electronic device may transmit the third event signal to the first external device via a wireless channel established with the first external device.

According to an embodiment, the wearable device 100 that receives the third event signal from the electronic device may control the operation of the wearable device 100, based on the third event signal. For example, the wearable device 100 may control the wearable device 100, based on the third event signal. The operations of the wearable device 100 based on the third event signal are described below in detail with reference to FIG. 17.

FIG. 15 is a flowchart of a method of controlling a wearable device based on an event signal corresponding to a connection of a fastening frame, according to an embodiment.

Operations 1510 to 1530 below may be performed by a wearable device (e.g., the wearable device 100 of FIG. 1).

In operation 1510, the wearable device may receive a first event signal from an electronic device connected to the wearable device via a wireless communication channel. When the first event signal is received from the electronic device, the wearable device may determine that the housing is connected to the fastening frame.

According to an embodiment, when the first event signal is received, the wearable device may electrically connect a motor driver circuit (e.g., the motor driver circuit 312 of FIG. 3) to a motor (e.g., the motor 534 of FIG. 3).

In operation 1520, when the first event signal is received, the wearable device may determine, based on sensing data, a value of a torque for controlling the wearable device. For example, the sensing data may include an angle sensed by the angle sensor 125 of FIG. 1. For example, the sensing data may include a change in acceleration and/or angular velocity according to the motion of the user 110, sensed by the inertial measurement device 135 of FIG. 1.

According to an embodiment, the wearable device may determine, based on the sensing data, a value of a torque for an exercise mode set in the wearable device. For example, when the exercise mode is a walking mode, the value of the torque for the walking of the user may be determined. For example, when the exercise mode is a stationary exercise mode, the value of the torque for the stationary exercise of the user may be determined.

In operation 1530, the wearable device may control the wearable device by outputting the value of the torque through a motor driver circuit. For example, the wearable device may output the value of the torque only when a housing of a thigh fastening portion is connected to a fastening frame.

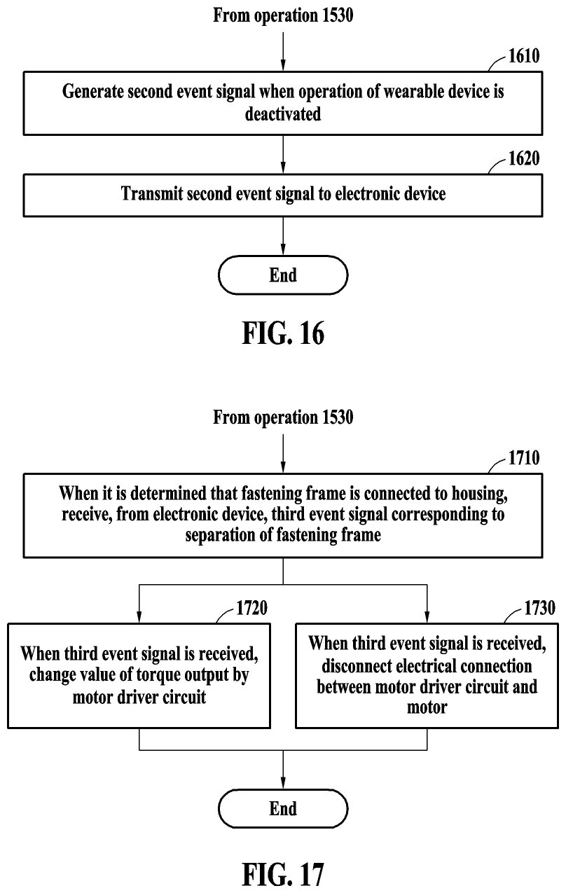

FIG. 16 is a flowchart of a method of transmitting, to an electronic device, an event signal corresponding to deactivation of an operation of a wearable device, according to an embodiment.

According to an embodiment, operations 1610 and 1620 may be performed after operation 1530 described above with reference to FIG. 15 is performed. Operations 1610 and 1620 may be performed by the electronic device (e.g., the wearable device 100 of FIG. 1).

In operation 1610, the wearable device may generate a second event signal when the operation of the wearable device is deactivated.

According to an embodiment, a deactivation mode may be a mode or a state in which no torque is output by the wearable device 100. For example, when an input to power off the wearable device 100 is received, the mode of the wearable device 100 may be switched to the deactivation mode. For example, when an exercise mode set (or performed) on the wearable device 100 is terminated, the mode of the wearable device 100 may be switched to the deactivation mode.

In operation 1620, the wearable device may transmit a second event signal to the electronic device connected to the wearable device via a wireless communication channel.

According to an embodiment, the electronic device may terminate the operation of the electronic device, in response to reception of the second event signal. For example, termination of the operation of the electronic device may be switching the operation mode of the electronic device to a sleep mode. For example, the electronic device may power off the electronic device when the second event signal is received.

FIG. 17 is a flowchart of a method of controlling a wearable device based on an event signal corresponding to separation of a fastening frame, according to an embodiment.

According to an embodiment, operations 1710 to 1730 may be performed after operation 1530 described above with reference to FIG. 15 is performed. Operations 1710 to 1730 below may be performed by a wearable device (e.g., the wearable device 100 of FIG. 1). According to an embodiment, operations 1720 and 1730 may be optionally performed.

In operation 1710, when it is determined that the fastening frame is connected to the housing, the wearable device may receive, from an electronic device (e.g., the electronic device 400 of FIG. 8), a third event signal corresponding to separation of the fastening frame. For example, the wearable device may receive the third event signal from the electronic device connected to the wearable device via a wireless communication channel.

In operation 1720, when receiving the third event signal, the wearable device may change a value of a torque output by a motor driver circuit. For example, the wearable device may change the value of the torque to a preset value. The preset value of the torque may be 0.

In operation 1730, when receiving the third event signal, the wearable device may disconnect the electrical connection between the motor driver circuit and the motor. For example, as the electrical connection between the motor driver circuit and the motor is released, a torque may not be output by the motor.

According to an embodiment, an electronic device 800 for detecting a connection of a fastening frame may include a communication module 810 configured to perform short-range wireless communication with an external device 100, 210, wherein the communication module may include at least one processor comprising processing circuitry, a switch configured to power on the electronic device when a fastening frame 920 is fastened to at least a portion of a housing 910 including the electronic device, a sensor module 820 configured to sense a magnetic flux 930 of a magnetic body 921 included in the fastening frame, and memory 850 comprising one or more storage media storing instructions.

According to an embodiment, the instructions, when executed by the at least one processor individually or collectively, may cause the electronic device 800 to perform at least: operation 1010 of receiving a magnetic flux value sensed by a sensor module, operation 1020 of determining that the fastening frame is connected, directly or indirectly, to the housing when the received magnetic flux value is greater than or equal to a preset threshold value, and operation 1030 of transmitting, to a first external device, a first event signal corresponding to a connection between the fastening frame and the housing.

According to an embodiment, the electronic device may further include a battery 840 configured to supply power to the electronic device.

According to an embodiment, the communication module may establish a wireless communication channel with the first external device 100, 210 by using BLE.

According to an embodiment, when the fastening frame is connected, directly or indirectly, to at least a portion of the housing, the switch may have a mechanical structure that is pressed by the fastening frame.

According to an embodiment, the first external device may include a wearable device 100, and the housing of the electronic device may be mechanically connected, directly or indirectly, to the wearable device.

According to an embodiment, the first external device may include a mobile terminal.

According to an embodiment, the instructions, when executed by the at least one processor individually or collectively, may further cause the electronic device 800 to perform at least: operation 1110 of receiving information about a communication module of a first external device from a second external device 210 and operation 1120 of establishing a wireless communication channel with the first external device, based on the information about a communication module of the first external device.

According to an embodiment, the operation of receiving, from the second external device, the information about a communication module of the first external device may include receiving, from the second external device via NFC, information about the communication module of the first external device.

According to an embodiment, the information about the communication module of the first external device may include a MAC address of the communication module of the first external device for use of BLE.

According to an embodiment, the instructions, when executed by the at least one processor individually or collectively, may further cause the electronic device 800 to perform at least: operation 1210 of receiving, from the first external device, a second event signal for deactivation of the first external device and operation 1220 of terminating the operation of the electronic device, in response to reception of the second event signal.

According to an embodiment, the instructions, when executed by the at least one processor individually or collectively, may further cause the electronic device 800 to perform at least: operation 1310 of repeatedly propagating a beacon for establishing a wireless communication channel with the first external device and operation 1320 of terminating the operation of the electronic device when there is no response from the first external device to the beacon within a preset time period.

According to an embodiment, the instructions, when executed by the at least one processor individually or collectively, may further cause the electronic device 800 to perform at least: operation 1410 of determining whether a second magnetic flux value sensed by a sensor module is less than a preset second threshold value when it is determined that the fastening frame is connected, directly or indirectly, to the housing, operation 1420 of generating a third event signal corresponding to separation of the fastening frame when the second magnetic flux value sensed by the sensor module is less than the preset second threshold value, and operation 1430 of transmitting the third event signal to the first external device.

According to an embodiment, a method of detecting a connection of a fastening frame 920, performed by an electronic device 800, may include operation 1010 of receiving a magnetic flux 930 value sensed by a sensor module 820 of the electronic device 800, when the received magnetic flux value is greater than or equal to a preset threshold value, operation 1020 of determining that the fastening frame is connected to a housing 910 of the electronic device, and operation 1030 of transmitting, to a first external device, a first event signal corresponding to a connection between the fastening frame and the housing.

According to an embodiment, a method of controlling a wearable device, performed by a wearable device 100, may include operation 1510 of receiving, from an electronic device 800 connected to the wearable device via a wireless communication channel, a first event signal, wherein the first event signal is generated by the electronic device when a fastening frame 920 is connected to at least a portion of the housing 910 including the electronic device, when the first event signal is received, operation 1520 of determining, based on sensing data, a value of a torque for controlling the wearable device, and operation 1530 of controlling the wearable device by outputting the value of the torque through a motor driver circuit 532 of the wearable device. “Based on” as used herein covers based at least on.

According to an embodiment, the housing of the electronic device may be mechanically connected, directly or indirectly, to the wearable device. “Connected” as used herein covers direct and indirect connections.

According to an embodiment, the method of controlling the wearable device may further include an operation of electrically connecting a motor driver circuit to a motor when the first event signal is received.

According to an embodiment, the method may include operation 1610 of generating a second event signal when the operation of the wearable device is deactivated and operation 1620 of transmitting the second event signal to the electronic device.

According to an embodiment, when the second event signal is received by the electronic device, the operation of the electronic device may be terminated.

According to an embodiment, the method of controlling the wearable device may further include operation 1710 of receiving, from the electronic device, a third event signal corresponding to separation of the fastening frame when it is determined that the fastening frame is connected, directly or indirectly, to the housing and operation 1720 of changing a value of a torque output by the motor driver circuit when the third event signal is received.

According to an embodiment, the method of controlling the wearable device may further include operation 1710 of receiving, from the electronic device, a third event signal corresponding to separation of the fastening frame when it is determined that the fastening frame is connected, directly or indirectly, to the housing and operation 1730 of disconnecting an electrical connection between the motor driver circuit and the motor when the third event signal is received.

The embodiments described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, a field-programmable gate array (FPGA), a programmable logic unit (PLU), a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is singular; however, one of ordinary skill in the art will appreciate that a processing device may include multiple processing elements and multiple types of processing elements. For example, the processing device may include a plurality of processors, or a single processor and a single controller. In addition, different processing configurations are possible, such as parallel processors.

The software may include a computer program, a piece of code, an instruction, or one or more combinations thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the embodiments described herein may be recorded in non-transitory computer-readable media including program instructions to implement various operations of the embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs and/or DVDs; magneto-optical media such as optical discs; and hardware devices that are specially configured to store and perform program instructions, such as read-only memory (ROM), RAM, flash memory, and the like. Examples of program instructions include both machine code, such as produced by a compiler, and files containing higher-level code that may be executed by the computer using an interpreter.

The above-described hardware devices may be configured to act as one or more software modules in order to perform the operations of the above-described examples, or vice versa.

As described above, although the embodiments have been described with reference to the limited drawings, one of ordinary skill in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents. While the disclosure has been illustrated and described with reference to various embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

Therefore, other implementations, other embodiments, and equivalents to the claims are also within the scope of the following claims.

1. An electronic device comprising:
a communication module configured to perform short-range wireless communication with an external device, wherein the communication module comprises at least one processor comprising processing circuitry;
a switch configured to power on the electronic device when a fastening frame is fastened to at least a portion of a housing of the electronic device;
a sensor module configured to sense a magnetic flux of a magnetic body comprised in the fastening frame; and
memory comprising one or more storage media storing instructions, when executed by the at least one processor individually or collectively, cause the electronic device to perform at least:
receiving a magnetic flux value sensed by the sensor module;
when the received magnetic flux value is greater than or equal to a preset threshold value, determining that the fastening frame is connected to the housing; and
transmitting, to a first external device, a first event signal corresponding to a connection between the fastening frame and the housing.

2. The electronic device of claim 1, further comprising:
a battery configured to supply power to the electronic device.

3. The electronic device of claim 1, wherein the communication module is configured to establish a wireless communication channel with the first external device by using Bluetooth low energy (BLE).

4. The electronic device of claim 1, wherein, when the fastening frame is connected to at least a portion of the housing, the switch has a mechanical structure configured to be pressed by the fastening frame.

5. The electronic device of claim 1, wherein
the first external device comprises a wearable device, and
the housing of the electronic device is mechanically connected to the wearable device.

6. The electronic device of claim 1, wherein the first external device comprises a mobile terminal.

7. The electronic device of claim 1, wherein the instructions, when executed by the at least one processor individually or collectively, further cause the electronic device to perform at least:
receiving information about a communication module of the first external device from a second external device; and
establishing, based on the information about the communication module of the first external device, a wireless communication channel with the first external device.

8. The electronic device of claim 7, wherein the receiving of the information about the communication module of the first external device from the second external device comprises receiving the information about the communication module of the first external device from the second external device via near field communication (NFC).

9. The electronic device of claim 7, wherein the information about the communication module of the first external device comprises a media access control (MAC) address of the communication module of the first external device for use of Bluetooth low energy (BLE).

10. The electronic device of claim 1, wherein the instructions, when executed by the at least one processor individually or collectively, further cause the electronic device to perform at least:
receiving a second event signal for deactivation of the first external device from the first external device; and
terminating an operation of the electronic device, in response to the receiving of the second event signal.

11. The electronic device of claim 1, wherein the instructions, when executed by the at least one processor individually or collectively, further cause the electronic device to perform at least:
repeatedly propagating a beacon for establishing a wireless communication channel with the first external device; and
when there is no response from the first external device to the beacon, terminating an operation of the electronic device.

12. The electronic device of claim 1, wherein the instructions, when executed by the at least one processor individually or collectively, further cause the electronic device to perform at least:
in a state in which it is determined that the fastening frame is connected to the housing, determining whether a second magnetic flux value sensed by the sensor module is less than a preset second threshold value;
when the second magnetic flux value sensed by the sensor module is less than the preset second threshold value, generating a third event signal corresponding to separation of the fastening frame; and
transmitting the third event signal to the first external device.

13. A method performed by an electronic device comprising:
receiving a magnetic flux value sensed by a sensor module of the electronic device;
when the received magnetic flux value is greater than or equal to a preset threshold value, determining that a fastening frame is connected to a housing of the electronic device; and
transmitting, to a first external device, a first event signal corresponding to a connection between the fastening frame and the housing.

14. A method performed by a wearable device comprising:
receiving, from an electronic device connected to the wearable device via a wireless communication channel, a first event signal, wherein the first event signal is generated by the electronic device when a fastening frame is connected to at least a portion of a housing comprising the electronic device;
when the first event signal is received, determining, based on sensing data, a value of a torque for controlling the wearable device; and
controlling the wearable device by outputting the value of the torque through a motor driver circuit of the wearable device.

15. The method of claim 14, wherein
the housing of the electronic device is mechanically connected to the wearable device.

16. The method of claim 14, further comprising:
when the first event signal is received, electrically connecting the motor driver circuit to a motor.

17. The method of claim 14, further comprising:
generating a second event signal when an operation of the wearable device is deactivated; and
transmitting, to the electronic device, the second event signal.

18. The method of claim 17, wherein
when the second event signal is received by the electronic device, an operation of the electronic device is terminated.

19. The method of claim 14, further comprising:
receiving a third event signal corresponding to separation of the fastening frame from the electronic device, when it is determined that the fastening frame is connected to the housing; and
changing, when the third event signal is received, a value of the torque output by the motor driver circuit.

20. The method of claim 14, further comprising:
receiving a third event signal corresponding to separation of the fastening frame from the electronic device, when it is determined that the fastening frame is connected to the housing; and
disconnecting, when receiving the third event signal, an electrical connection between the motor driver circuit and a motor.
